(19) United States
(12) Patent Application Publication
(10) Pub. No.: US 2007/0166839 A1
(43) Pub. Date: Jul. 19, 2007

(54) METHOD FOR FABRICATING MAGNETORESISTANCE MULTI-LAYER

(76) Inventors: Chih-Huang Lai, Hsinchu City (TW); Sheng-Huang Huang, Tainan City (TW); Cheng-Han Yang, Kaohsiung City (TW); Yung-Hung Wang, Taoyuan County (TW); Wei-Chuan Chen, Taipei County (TW); Kuei-Hung Shen, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,831

(22) Filed: May 12, 2006

(30) Foreign Application Priority Data
Jan. 18, 2006 (TW) 95101888

(51) Int. Cl. H01L 21/00

(52) U.S. Cl. 438/3

(57) ABSTRACT

A fabrication method of a magnetoresistance multi-layer is provided. The method includes forming a multi-layer with at least an antiferromagnetic layer and performing an ion irradiation process to the multi-layer to transform a disordered structure of the antiferromagnetic layer to an ordered structure. Accordingly, the process time can be reduced and the interdiffusion in the multi-layer can be prevented.

### CROSS-REFERENCE TO RELATED APPLICATION

This application claims the priority benefit of Taiwan application serial no. 95101888, filed on Jan. 18, 2006. All disclosure of the Taiwan application is incorporated herein by reference.

### BACKGROUND OF THE INVENTION

1. Field of the Invention

The present invention relates to a method for fabricating a magnetoresistance multilayer. More particularly, the present invention relates to a fabrication wherein the antiferromagnetic metal layer in the magnetoresistance multi-layer is ordered using ion irradiation.

2. Description of Related Art

The exchange anisotropy between ferromagnets and antiferromagnets can be applied to spin-valve based read heads and magnetic memory devices. The study of exchange anisotropy is thereby an important and popular subject in the field of magnet.

In spin-valve based read heads and magnetic memory devices, the film layer structure mainly includes an antiferromagnetic biasing layer, a pinned layer immediately adjacent to the biasing layer, a nonmagnetic spacer and a magnetic free layer. Due to the exchange coupling effect between the ferromagnetic/antiferromagnetic layer, an unidirectional anisotropy is induced in the pinned layer and an unidirectional shift in the hysteresis loop of the pinned layer is observed. The extent of the shifting is known as an exchange field or exchange bias field. When an external magnetic field smaller than the exchange field is applied along the easy axis direction, the magnetization direction of the free layer aligns along the direction of the external magnetic field, while the magnetization direction of the pinned layer is unaffected by the external magnetic field. Accordingly, by altering the direction of the external magnetic field, the parallel and anti-parallel arrangements of the magnetization directions of the free layer and the pinned layer can be controlled.

In a giant magnetoresistance spin valve (GMR) or a magnetic tunnel junction (MTJ), the multi-layer film has low resistance (parallel arrangement) and high resistance (anti-parallel arrangement) according to the differential spin scattering theory or the spin dependent tunneling theory. In application, it is preferable to have a greater exchange field in order to maximize the operable magnetic field region. Further, the exchange field is a function of temperature. As the temperature increases, thermal fluctuation will destroy the ferromagnetic/antiferromagnetic exchange coupling effect. Accordingly, to have a better thermal stability is preferred during application. Moreover, chemical stability is also an important factor to be considered. The three characteristics discussed above greatly affects the appropriate selection of an antiferromagnetic material.

Among the various antiferromagnetic materials that are being developed, PtMn comprises desirable thermal and chemical stabilities. Further, a greater exchange field can also be provided by PtMn. Therefore, PtMn is the best candidate among the various antiferrogmagnet materials. However, there is a drawback in the fabrication process of PtMn. In order for the crystalline structure of PtMn to transform from a disordered FCC structure to an ordered FCT structure to have the antiferromagentic characteristics, PtMn must be subjected to a post-anneal treatment. Further, an external electric field is concurrently applied during the post-anneal treatment to establish the easy axis direction.

However, not only the length post-anneal process extends the process time, interdiffusion often occurs between the film layers, and a mixing of the film interface is resulted. The magnetic properties of the multi-layer film are thereby altered, and the magneto-resistance ratio is also lower.

The U.S. Pat. No. 6,383,597 discloses an ion irradiation process, in which an ordered FePt₃ thin film is grown on a substrate plate heated to 750 degrees Celsius, followed by using a patterned mask and a lower energy nitrogen ions (N⁺) irradiation to transform the ordered FePt₃ thin film to a disordered thin film. An ordered phase and a disordered phase of a FePt₃ thin film exhibit significantly different magnetic properties. These properties can be applied to control the position of a magnetic region.

The U.S. Pat. No. 6,383,597 discloses an ion irradiation process, wherein with a patterned mask, a low energy N⁺ ion irradiation is employed to destroy the interface of CoCrPtB/Ru/CoCrPtB in order for the anti-parallel magnetic moments in the two CoCrPtB layers to disappear. This method is used to define the position of the magnetic region. However, the above patents rely on low energy ion irradiation process to disrupt the lattice of an ordered ferromagnetic layer to achieve obvious changes in the magnetic properties.

### SUMMARY OF THE INVENTION

The present invention provides a fabrication method of a magnetoresistance multi-layer film, in which high energy ion irradiation process is used to order antiferromagnetic metal layer. Accordingly, the ordering temperature of an antiferromagnetic layer can be lowered and the process time can be reduced to obviate interdiffusions in the film layer.

The present invention also provides a fabrication method of a magnetoresistance multi-layer film, wherein an ion irradiation process can create exchange fields of various directions on a single wafer that has a magnetic multi-layer film.

The present invention provides a fabrication method of a magnetoresistance multi-layer film. The method includes forming a multi-layer film, wherein the multi-layer film at least includes an antiferromagnetic metal layer, and performing an ion irradiation process on the multi-layer film to transform the antiferromagnetic film from a disordered structure to an ordered structure in order to acquire the antiferromagnetic characteristics.

The present invention provides another fabrication method of a magnetoresistance multi-layer film. The method includes forming a multi-layer film on a wafer, wherein the multi-layer film includes at least an antiferromagnetic metal layer. A magnetic field is provided to the wafer, and a direction of the magnetic field is a first direction, for example. Further, an ion irradiation process is performed on a first region of the wafer in order for the antiferromagnetic metal layer in the first region to transform from a disordered structure to an ordered structure. Accordingly, the easy axis direction of the first region is established along the first direction of the magnetic field. Thereafter, the easy axis direction of the antiferromagnetic metal layer in the first region or the direction of the magnetic field is changed to a second direction. An ion irradiation process is then performed on the second region of the wafer to transform the second region of the antiferromagnetic metal layer from a disordered structure to an ordered structure. The easy axis direction of the antiferromagnetic metal layer in the second region is aligned along the direction of the magnetic field.

According to the fabrication method of a magnetoresistance multi-layer film, the first direction is different from a second direction.

According to the fabrication method of a magnetoresistance multi-layer film, a material that constitutes the antiferromagnetic metal layer includes PtMn.

According to the fabrication method of a magnetoresistance multi-layer film, the multi-layer film includes at least a stack layer formed with a first ferromagnetic metal layer, a non-ferromagnetic metal layer, and a second ferromagnetic metal layer, wherein the antiferromagnetic metal layer is contiguous to either the first ferromagnetic layer or the second ferromagnetic layer.

In the above fabrication method of a magnetoresistance multi-layer film, the ions used in the ion irradiation process includes helium ions or hydrogen ions.

In the above fabrication method of a magnetoresistance multi-layer film, the implantation energy used in the ion irradiation process is sufficiently high for the ions to completely penetrate through the film layer.

Accordingly, the present invention applies a higher energy ion irradiation process to order the antiferromagnetic metal layer. Comparing with the conventional length post anneal process, the method of the present invention can lower the ordering temperature of the antiferromagnetic metal layer and shorten the process temperature. Further, an interdiffusion in film layer, resulting in a decline of the magneto-resistance, is prevented.

Moreover, the present invention relies on an application of a patterned mask layer to select different regions on the magnetic multi-layer film to perform the ion irradiation process, wherein the ion irradiation process is conducted along with the changing of the applied field direction. As a result, a plurality of magnetoresistance device units that comprise different exchange field directions can be formed on a single wafer.

Several exemplary embodiments of the invention will now be described in detail with reference to the accompanying drawings. It is to be understood that the foregoing general description and the following detailed description of preferred purposes, features, and merits are exemplary and explanatory towards the principles of the invention only and are not restrictive of the invention, as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram showing the method for fabricating a magnetoresistance multi-layer film according to a first embodiment of the present invention.

FIG. 2 is a diagram showing the magnetic hysteresis loops of a CoFe/PtMn bilayer film structure before and after ion irradiation.

FIG. 3 is a diagram showing the results of an x-ray diffraction analysis on a CoFe/PtMn bilayer film structure before and after ion irradiation.

FIG. 4 is a diagram showing the magnetic hysteresis loops of a giant magnetoresistance structure using PtMn as an antiferromagnetic metal layer.

FIG. 5 is a diagram showing the magneto-resistance of a giant magnetoresistance structure using PtMn as an antiferromagnetic metal layer.

FIG. 6 is a plot illustrating the relationship between ion dose and magneto-resistance of a giant magnetoresistance structure using PtMn as an antiferromagnetic metal layer.

FIGS. 7A-7B are schematic diagrams showing the fabrication method of a magnetoresistance multi-layer film according to a second embodiment of the present invention.

### DESCRIPTION OF THE PREFERRED EMBODIMENTS

Reference will now be made in detail to the present preferred embodiments of the invention. It is to be understood that both the foregoing general description and the following detailed description are exemplary, and are intended to provide further explanation of the invention as claimed.

### Embodiment I

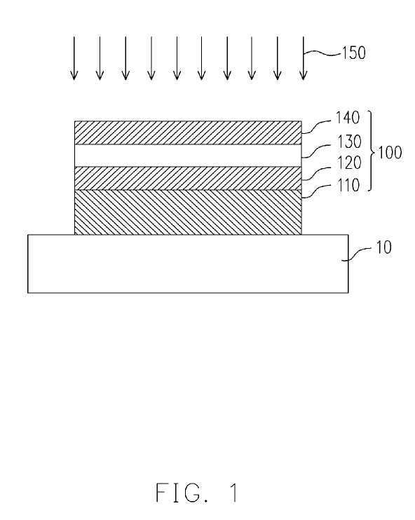

FIG. 1 is a schematic diagram illustration the fabrication method of a magnetoresistance multi-layer film according to the first embodiment of the present invention. As shown in FIG. 1, the fabrication method of a magnetoresistance multi-layer film of the present invention includes performing an ion irradiation process 150 on a multi-layer film 100 that includes an antiferromagentic metal layer 110. The disordered structure of the antiferromagnetic metal layer 110 is then transformed to an ordered structure. The basis structure of the magnetoresistance multi-layer film (MTJ multi-layer film) of this embodiment includes an antiferromagnetic metal layer 110 (bias layer), a magnetic metal layer 120 (pinned layer) immediately adjacent to the antiferromagnetic metal layer 110, a non-magnetic metal layer 130 (spacer layer) and a ferromagnetic metal layer 140 (free layer), wherein the magnetoresistance multi-layer film is formed on a substrate 10. Moreover, the above ion irradiation process 150 can be conducted as a magnetic field being applied to the multi-layer film 100 to establish the easy axis direction of the antiferromagnetic metal layer 110.

The substrate 10 includes but not limited to a silicon substrate or a metal conductive line. A material of the antiferromagnetic metal layer 110 includes PtMn, for example, while a material of the ferromagnetic metal layers 120, 140 includes but not limited to CoFe or NiFe. A material of the non-magnetic layer 130 includes Cu, for example. A method of forming these metal film layers includes, vapor deposition or sputtering, for example. Moreover, the antiferromagnetic metal layer 110 can also be contiguously above the ferromagnetic metal layer 140 for the ferromagnetic metal layer 140 to serve as a pinned layer and for the magnetic metal layer 120 to serve as a free layer.

In the fabrication method illustrated in FIG. 1, the ions used in the ion irradiation process 150 are preferably lighter ions, such as helium ions or hydrogen ions. Further, an irradiation energy applied in the ion irradiation process is sufficiently high for the ions to completely penetrate through the film layer 100 to the substrate 10. In this embodiment of the invention, the ion irradiation process 150 is conducted with an accelerated voltage of about 2 millions electronic volts (eVolts), an irradiation current density of about 0.8 to 3 μA/cm², a dosage of about 8×10¹⁵ to 2×10¹⁶ ions/cm², and at an operating temperature of about 150° C. to about 300° C.

Although the disclosure herein refers to certain illustrated embodiments as in FIG. 1, it is to be understood that these embodiments are presented by way of example and not by way of limitation. For example, the present invention may include forming a protective layer on the ferromagnetic metal layer 140 or forming a more complicated multi-layer film 100 as the magento-resistance multi-layer.

According to the above-mentioned fabrication process in the first embodiment, the present invention applies a higher energy ion irradiation process to order the antiferromagnetic metal layer in order to lower the ordering temperature of the antiferromagnetic metal layer and to shorten the process time. Further, interdiffusion generated in the film layer leading to a decline of the magnetoresistance is prevented.

Experiments

(I) CoFe/PtMn Bilayer Film Structure

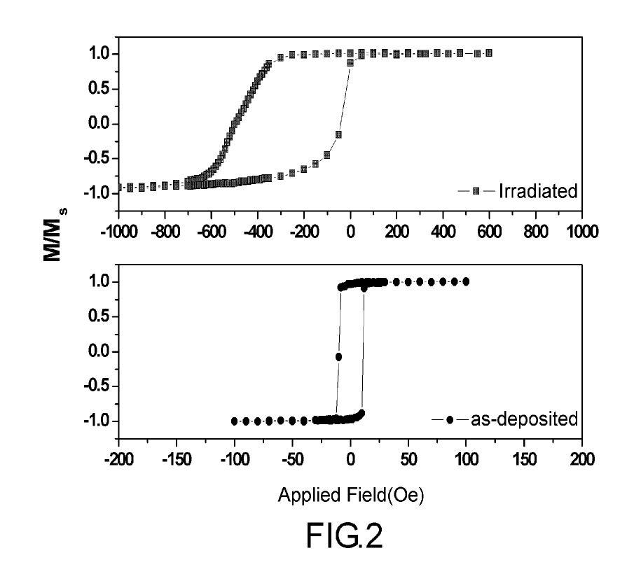

A CoFe/PtMn bilayer film structure is formed, wherein the stack structure of the bilayer film includes sequentially Si, NiFeCr (5 nm), CoFe (10 nm), PtMn (20 nm) and NiFeCr (5 nm). The magnetic properties of the bilayer film are measured before ion irradiation. An ion irradiation process is then conducted on the bilayer film structure, wherein the operating parameters of the ion irradiation process include helium ions, an irradiation energy of about 2 millions eVolts, a dosage of about 1.91×10¹⁶ ions/cm², an irradiation current density of about 1.08 μA/cm². The magnetic properties of the bilayer film are again measured subsequent to the ion irradiation process. The measured parameters of the magnetic properties of the film layer pre and post ion irradiation are illustrated in FIGS. 2 & 3.

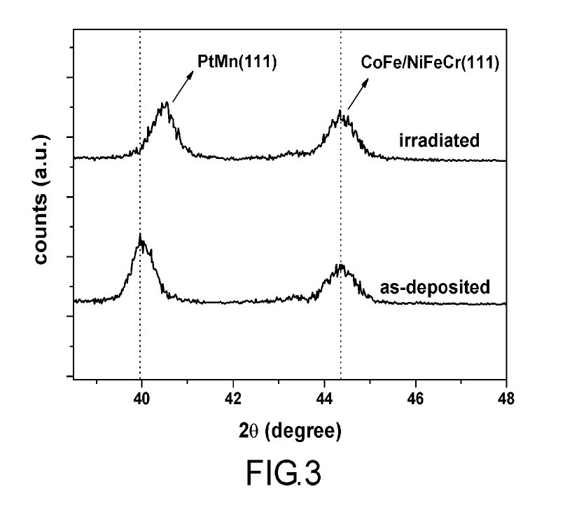

FIG. 2 is a diagram showing the magnetic hysteresis loops of a CoFe/PtMn bilayer film structure before and after ion irradiation, while FIG. 3 is an diagram showing the results of an X-ray diffraction analysis on a CoFe/PtMn bilayer film structure before and after ion irradiation. As shown in FIG. 2, the hysteresis loop of the bilayer film after the ion irradiation process suggests the presence of an exchange field. Further, from the diffraction peak of PtMn as shown in the results of the X-ray diffraction analysis in FIG. 3, PtMn has changed from a FCC phase to a FCT phase for the film structure to generate an exchange field.

(II) Using PtMn as an Antiferromagnetic Metal Layer of a Giant MagnetoResistance Structure

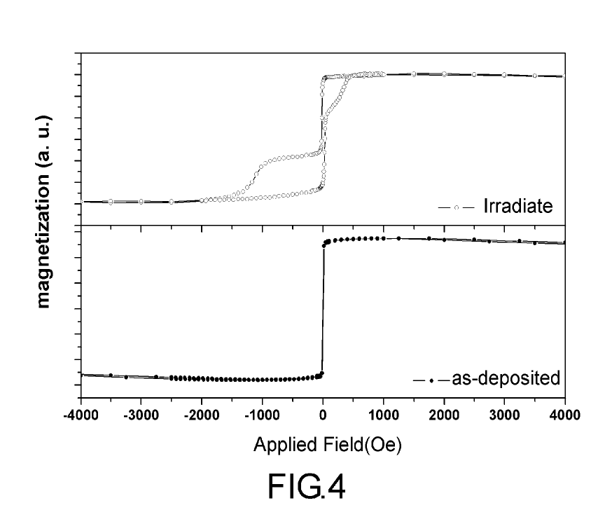

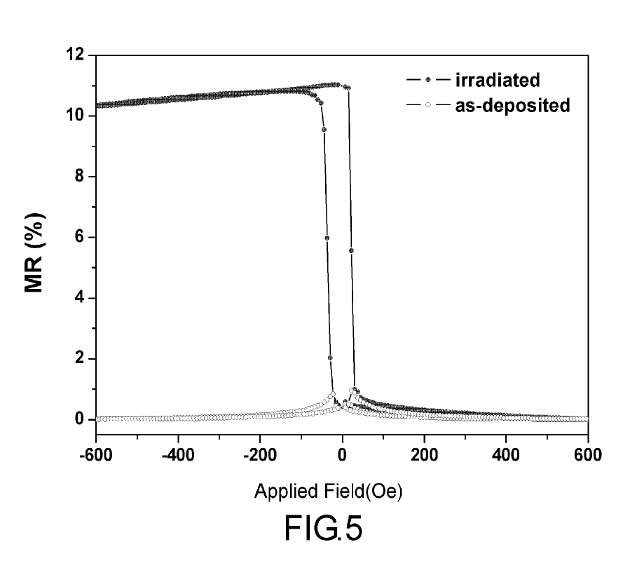

A giant magnetoresistance structure using PtMn as an antiferromagnetic metal layer is formed, wherein the stack structure of the film layer includes sequentially Si/NiFeCr (5 nm), NiFe (3 nm), CoFe (1.5 nm), Cu (2.6 nm), CoFe (2.2 nm), PtMn (20 nm) and NiFeCr (5 nm). The magnetic properties and the magnetoresistance of the giant magnetoresistance structure are measured. Thereafter, an ion irradiation process is performed, wherein the operating parameters of the ion irradiation process include helium ions, irradiation energy of about 2 millions eVolts, a dosage of about 1.91×10¹⁶ ions/cm², and an irradiation current density of about 1.08 μA/cm². The magnetic properties and the magnetoresistance of the giant magnetoresistance structure are measured subsequent to the ion irradiation process, and the results are illustrated in FIGS. 4 and 5.

FIG. 4 is a diagram showing the magnetic hysteresis loops of a giant magnetoresistance structure using PtMn as an antiferromagnetic metal layer, while FIG. 5 is a diagram showing the magneto-resistance of a giant magnetoresistance structure using PtMn as an antiferromagnetic metal layer. As shown in FIG. 4, subsequent to the ion irradiation process, PtMn is transformed from a disordered structure in to an ordered structure to form an antiferromagentic phase, and is transformed from having no exchange field properties as in the lower diagram of FIG. 4 to a film generated with an exchange field as shown in the upper diagram of FIG. 4. As illustrated by the magneto-resistance curve in FIG. 5, before the ion irradiation process, the magneto-resistance ratio is very small. However, subsequent to the ion irradiation process, the magneto-resistance ratio approaches 11%.

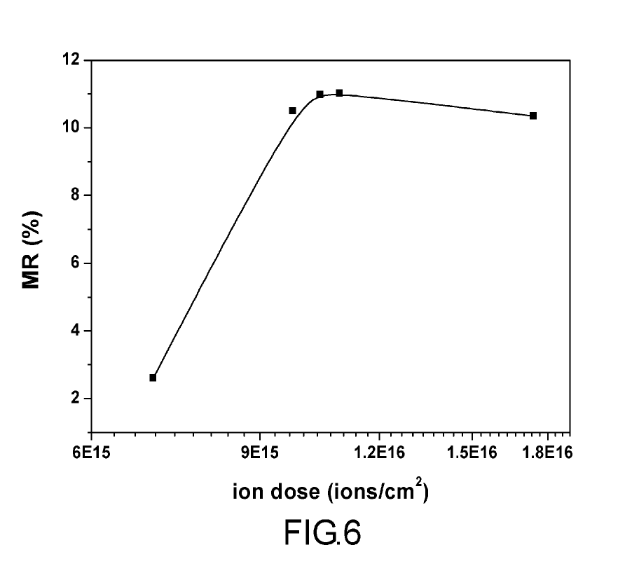

Continuing to FIG. 6, FIG. 6 is a plot illustrating the relationship between ion dose and magneto-resistance of a giant magnetoresistance structure using PtMn as an antiferromagnetic metal layer. The irradiation energy is controlled to about 2 millions eVolts. The current density is controlled to about 1.08 μA/cm². Different ion doses are then used to perform the irradiation process while the functional changes of magneto-resistance are measured. As shown in FIG. 6, when the ion dose is too low (lower than 1.2×10¹⁶ ions/cm²), PtMn fails to phase change to an antiferromagnetic layer because the heating time is too short. Consequently, the magneto-resistance ratio is extremely small. When the dosage reaches to 10¹⁶ to 1.2×10¹⁶ ions/cm², a more desirable magneto-resistance ratio is resulted. However, as the dosage becomes too high, the magneto-resistance ratio declines due to the destruction of the interface.

### Embodiment 2

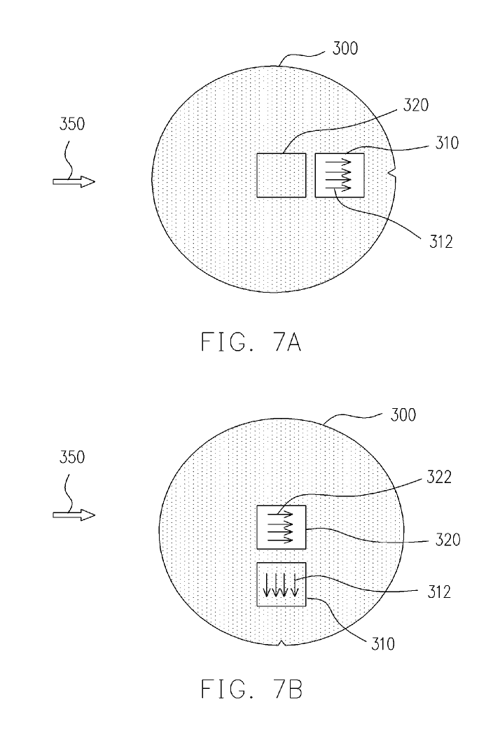

FIGS. 7A to 7B are schematic diagrams illustrating the fabrication method of a magnetoresistance multi-layer film according to a second embodiment of the present invention. As shown in FIG. 7A, a multi-layer film 300 is formed on a wafer (not shown), wherein the multi-layer film 300 is a stack layer that includes at least an antiferromagnetic metal layer and a ferromagnetic metal layer, a nonmagnetic metal layer, and a ferromagnetic metal layer, wherein the material of these film layers and the fabrication method are similar to those described in the first embodiment, and thus will not be further reiterated herein. Similar to the method in the first embodiment, the anti-ferromagnetic metal layer can form contiguously to one of the two ferromagnetic metal layers.

Referring to FIG. 7A, a mask layer (the dot patterns region in FIG. 7A) covers the multi-layer film 300, wherein only a first region 310 is exposed. An ion irradiation process is then performed on the wafer a magnetic field 350 of a first direction being applied outside the wafer. As a result, the antiferromagnetic metal layer of the first region 310 is transformed from a disordered structure to an ordered structure. Further, the easy axis direction 312 of the antiferromagnetic metal layer in the first region 310 aligns with the first direction of the magnetic field 350.

Thereafter, as shown in FIG. 7B, a mask is used to cover the multi-layer film 300, wherein a second region 320 is exposed by the mask. By spinning the wafer, the easy axis direction 312 of the antiferromagnetic layer in the first region 310 is changed to a second direction, wherein the first direction is different from a second direction. An ion irradiation process is then performed on the wafer while a magnetic field 350 of a first direction is applied outside the wafer. Consequently, the disordered structure of the antiferromagnetic metal in the second region 320 is transformed to an ordered structure. Moreover the easy axis direction 322 of the antiferromagnetic metal layer in the second region 320 aligns with the first direction of the magnetic field 350. As shown in FIG. 7B, the direction of the easy axis 312 of the antiferromagnetic metal layer in the first region 310 is different from the direction of the easy axis of the antiferromagnetic metal layer in the second region 310. In this embodiment, the applied field direction can be altered according to the spinning direction of the wafer. However, the applied field direction can also be altered by changing the direction of the magnetic field.

According to the fabrication method in the second embodiment, a plurality of magnetoresistance multi-layer film units having different exchange field directions can be formed on a single wafer by spinning the wafer or by altering the magnetic field direction to change the applied field direction and by using mask to perform a localized ion irradiation process on the multi-layer film 300.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabrication method of a magnetoresistance multi-layer film, the method comprising:
forming a multi-layer film comprising at least an antiferromagnetic metal layer; and
performing an ion irradiation process on the multi-layer film to transform the antiferromagnetic metal layer from a disordered structure to an ordered structure.

2. The method of claim 1, wherein the antiferromagnetic metal layer is formed with a material that comprises PtMn.

3. The method of claim 1, wherein the multi-layer film is further formed with a stack layer comprising a first ferromagnetic metal layer, a non-magnetic metal layer, a second ferromagnetic metal layer, wherein the antiferromagnetic is contiguous to either the first ferromagnetic metal layer or the second ferromagnetic metal layer.

4. The method of claim 1, wherein ions used in the ion irradiation process comprises helium ions or hydrogen ions.

5. The method of claim 1, wherein an irradiation energy of the ion irradiation process is sufficient for the ions to completely penetrate through the film layer.

6. The method of claim 1, wherein an irradiation energy of the ion irradiation process is about 2 millions eVolts.

7. The method of claim 1, wherein a current density of the ion irradiation process is about 0.8 to 3 μA/cm².

8. The method of claim 1, wherein a current density of the ion irradiation process is about 1.08 μA/cm².

9. The method of claim 1, wherein a dosage applied in the ion irradiation process is about 10⁶ to 1.2×10¹⁶ ions/cm².

10. A fabrication method of a magnetoresistance multi-layer film, wherein the method comprises at least:
forming a multi-layer film on a wafer, wherein the multi-layer film comprises at least an antiferromagnetic metal layer;
providing a magnetic field to the wafer, wherein a direction of the magnetic field is along a first direction;
performing an ion irradiation process on a first region of the wafer to transform the antiferromagnetic metal layer in the first region from a disordered structure to an ordered structure, wherein a direction of an easy axis of the antiferromagnetic metal layer in the first region is aligned with the first direction;
changing the direction of the easy axis of the antiferromagnetic metal layer or the direction of the magnetic field to a second direction; and
performing an ion irradiation process on a second region of the wafer to transform the antiferromagnetic metal layer in the second region to a disordered structure to an ordered structure, and aligning an easy axis of the antiferromagnetic metal layer in the second region with the direction of the magnetic field.

11. The method of claim 10, wherein the first direction is different from the second direction.

12. The method of claim 10, wherein the antiferromagnetic metal layer is formed with a material comprising PtMn.

13. The method of claim 10, wherein the multi-layer film at least comprises a stack layer formed with a ferromagnetic metal layer, a non-magnetic metal layer, a second ferromagnetic metal, wherein the antiferromagnetic metal layer is contiguous to the first ferromagnetic metal layer or the second ferromagnetic metal layer.

14. The method of claim 10, wherein ions used in the ion irradiation process comprises helium ions or hydrogen ions.

15. The method of claim 14, wherein an irradiation energy of the ion irradiation process is sufficient to completely penetrate through the film layer.
